(19) United States
(12) Patent Application Publication
(10) Pub. No.: US 2009/0174442 A1
(43) Pub. Date: Jul. 9, 2009

(54) Ramp generator and image sensor including the same

(76) Inventors: Soo Youn Kim, Seongnam-si (KR); Kyung Min Shin, Suwon-si (KR); Yong Lim, Suwon-si (KR)

Correspondence Address: HARNESS, DICKEY & PIERCE, P.L.C., P.O. BOX 8910, RESTON, VA, 20195, US

(21) Appl. No.: 12/318,361

(22) Filed: Dec. 29, 2008

(30) Foreign Application Priority Data
Dec. 26, 2007 (KR) 10-2007-0137599

(51) Int. Cl. H03K 4/06

(52) U.S. Cl. 327/134

(57) ABSTRACT

A ramp signal generator is provided. The ramp signal generator may include a ramp signal generation unit configured to generate a ramp signal based on an externally-supplied driving voltage and a ramp signal correction unit configured to feed back and compare the ramp signal with a reference signal and correct a driving voltage by generating a corrected voltage from a comparison value. The ramp signal generation unit may generate a corrected ramp signal where the slope changes based on a corrected driving voltage.

### PRIORITY STATEMENT

This application claims priority under 35 U.S.C. § 119 to Korean Patent Application No. 10-2007-0137599, filed on Dec. 26, 2007, in the Korean Intellectual Property Office (KIPO), the entire contents of which are incorporated by reference herein.

### BACKGROUND

1. Technical Field

Example embodiments relate to a ramp signal generator and an image sensor including the same, and more particularly, to a ramp signal generator capable of outputting a stable ramp signal by correcting a slope of a ramp signal automatically and an image sensor including the same.

2. Discussion of the Related Art

An image sensor is a device capturing an image by using a property of a semiconductor, which responds to light, and a CMOS image sensor is widely used, as the CMOS technique has been advancing. The CMOS image sensor uses a Correlated Double Sampling (CDS) method and outputs a signal sampled by a CDS method, e.g., the difference between a reset signal and an image signal, in a digital signal.

A ramp signal is used in order to output the difference between a reset signal and an image signal in a digital signal. In other words, a CMOS image sensor picks up the difference between the image signal and the reset signal which fluctuate according to the degree of external light, and converts and outputs it into a digital signal according to the slope of the ramp signal.

On the other hand, a ramp signal may be generated by a switched capacitor integrator. Such switched capacitor integrator may be composed of an OP-Amp, a plurality of capacitors, and a plurality of switches. However, the integrator may have an output ramp signal whose slope changes depending on a change in characteristics of elements, e.g., a plurality of capacitors or switches. Such slope change of the ramp signal may interrupt abnormal operation of a CMOS image sensor by causing a change of a digital signal to be output.

### SUMMARY

Example embodiments provide a ramp signal generator capable of correcting a changed slope of a ramp signal by using a correcting voltage. Example embodiments also provide an image sensor including such a ramp signal generator.

According to example embodiments, a ramp signal generator may include a ramp signal generation unit configured to generate a ramp signal based on an externally-supplied driving voltage, and a ramp signal correcting unit configured to feed back and compare the ramp signal with a reference signal and correct the externally-supplied driving voltage by generating a correcting voltage from the comparison value. The ramp signal generation unit may generate a slope-changed corrected ramp signal based on the corrected driving voltage.

According to example embodiments, an image sensor may include an active pixel sensor array configured to generate an image signal by sensing light, the ramp signal generating unit of example embodiments, and an analog to digital converter configured to perform correlated double sampling and convert an image signal to a digital signal using the slope-changed corrected ramp signal.

### BRIEF DESCRIPTION OF THE DRAWINGS

Example embodiments will be more clearly understood from the following detailed description taken in conjunction with the accompanying drawings. FIGS. 1-6 represent non-limiting, example embodiments as described herein.

FIG. 1 is a schematic block diagram of an image sensor including a ramp signal generator according to example embodiments;

FIG. 2 is a schematic block diagram of a ramp signal generator of FIG. 1;

FIG. 3 is an operational timing diagram of a ramp signal generation unit in FIG. 2;

FIG. 4 is a circuit diagram of a comparison unit in FIG. 3;

FIG. 5 is an operational timing diagram of a ramp signal correcting unit in FIG. 2; and

FIG. 6 is a signal wave diagram in a N1 node after a correcting voltage is generated.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Reference will now be made in detail to example embodiments illustrated in the accompanying drawings, wherein like reference numerals refer to the like elements throughout. Example embodiments may, however, be embodied in many different forms and should not be construed as limited to the example embodiments set forth herein. Rather, these example embodiments are provided so that this disclosure will be thorough and complete, and will fully convey the scope of example embodiments to those skilled in the art. In the drawings, the sizes and relative sizes of layers and regions may be exaggerated for clarity.

It will be understood that when an element or layer is referred to as being “on,” “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, e.g., “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms including technical and scientific terms used herein have the same meaning as commonly understood by one of ordinary skill in the art to which example embodiments belongs. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

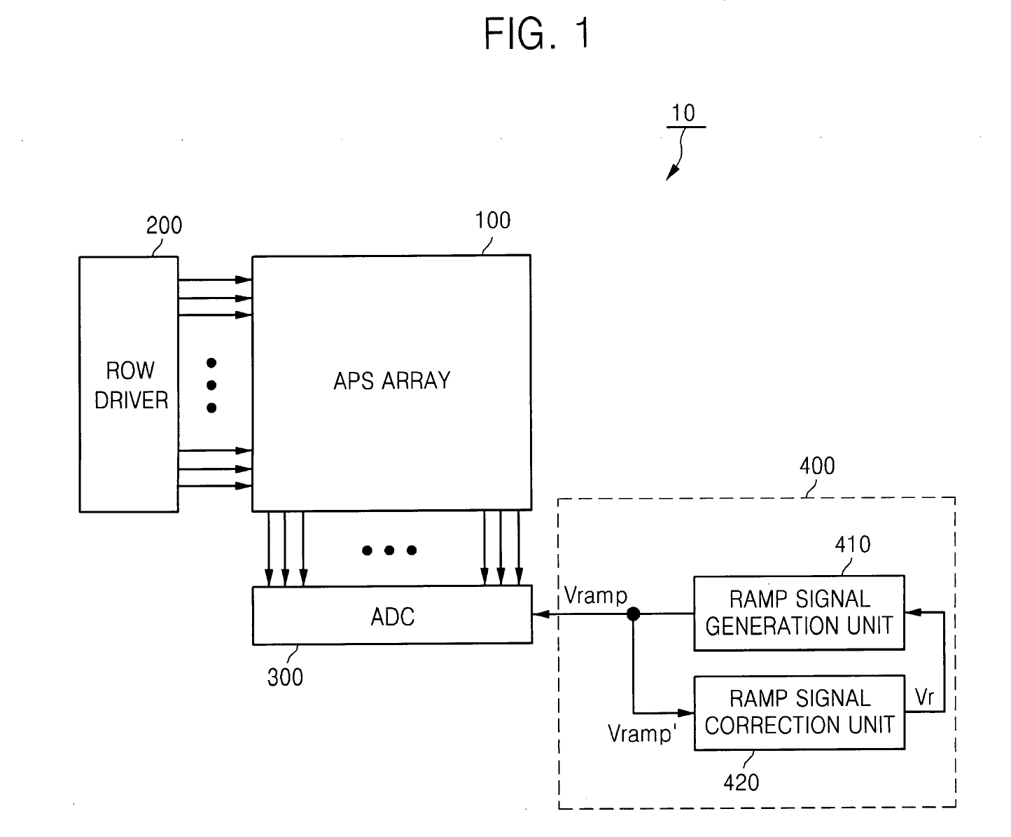

FIG. 1 is a schematic block diagram of an image sensor including a ramp signal generator according to example embodiments. Referring to FIG. 1, an image sensor 10 may include an Active Pixel Sensor (APS) array 100, a row driver 200, an analog to digital converter (ADC) 300, and a ramp signal generator 400. The APS array 100 may include a plurality of light sensitive elements, e.g., a photo diode, photo transistor, or a pinned photo diode. The APS array 100 may sense light by using the plurality of light sensitive elements and may generate an image signal by converting the sensed light to an electric signal.

The row driver 200 may drive an APS array 100 in the units of the row driver 200, or the row driver 200 may generate a row selection signal. In addition, the APS array 100 may output a reset signal and an image signal from a row, which is selected by the row selection signal supplied from the row driver 200, to the ADC 300.

The ADC 300 may convert an image signal output from the APS array 100 to a digital signal by using a ramp signal Vramp supplied from the ramp signal generator 400. For example, the ADC 300 may generate a digital signal by performing correlated double sampling (CDS) on a reset signal and an image signal, which are output from the APS array 100 using the ramp signal Vramp. The ramp signal generator 400 may generate and supply a ramp signal Vramp to the ADC 300. The ramp signal generator 400 may include a ramp signal generation unit 410 and a ramp signal correction unit 420.

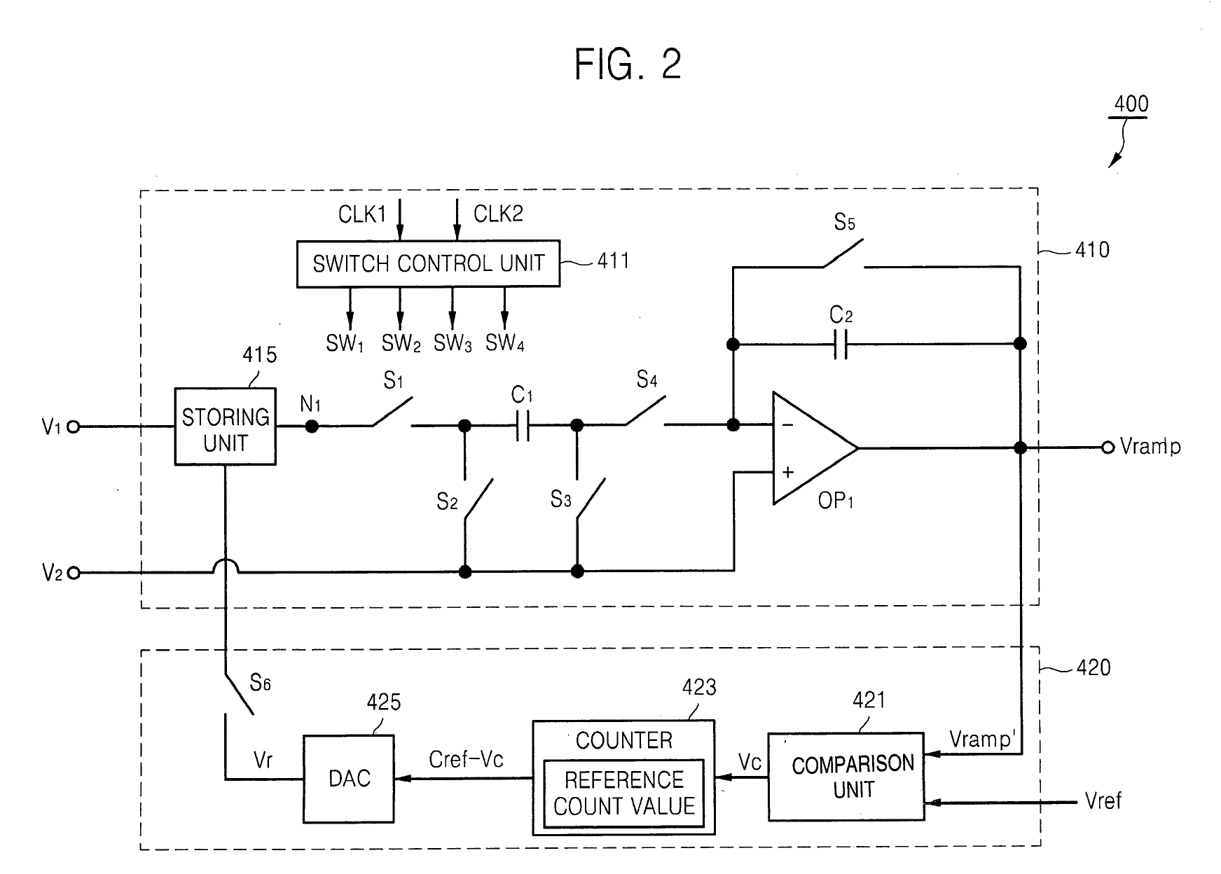

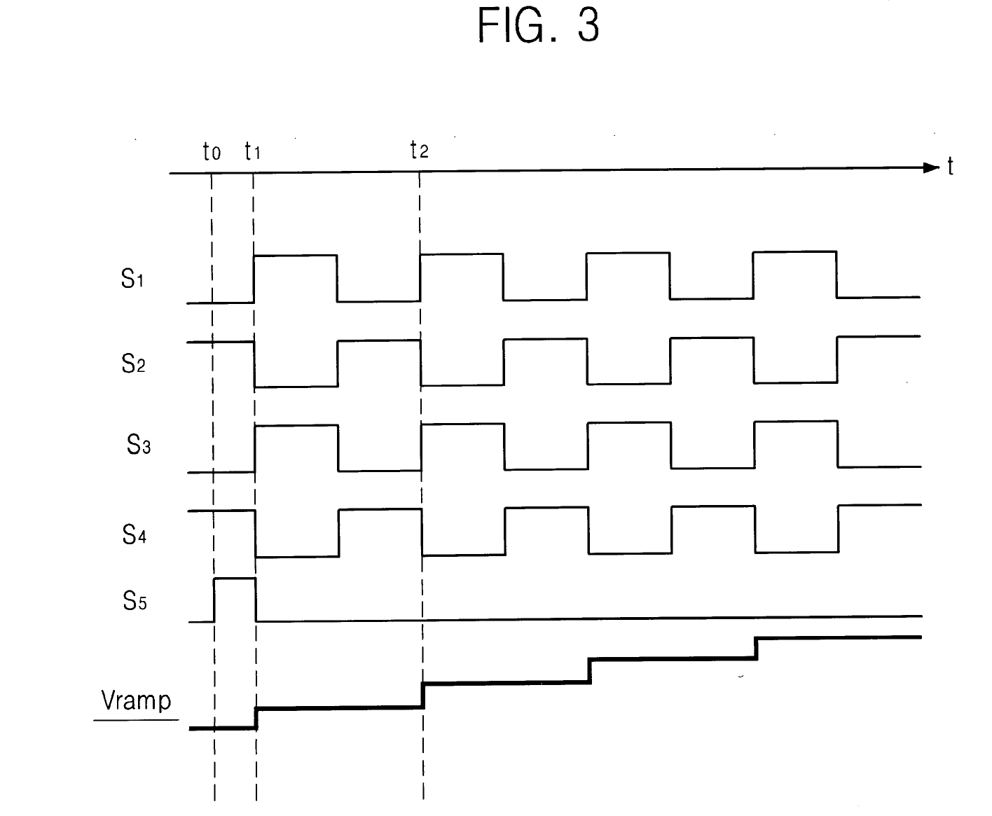

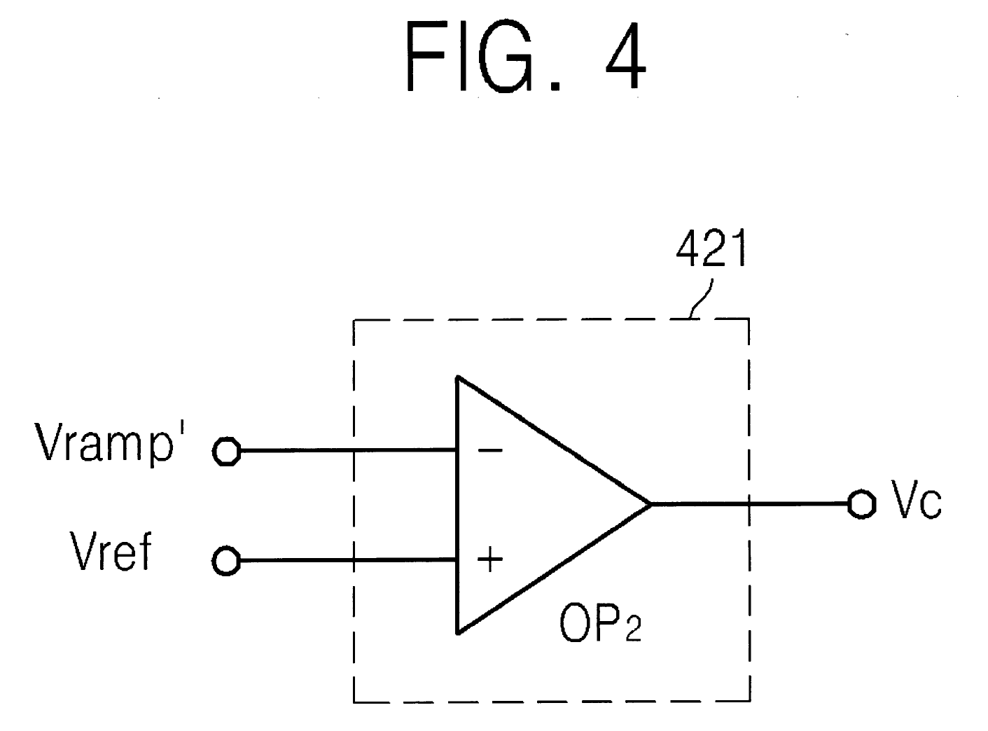

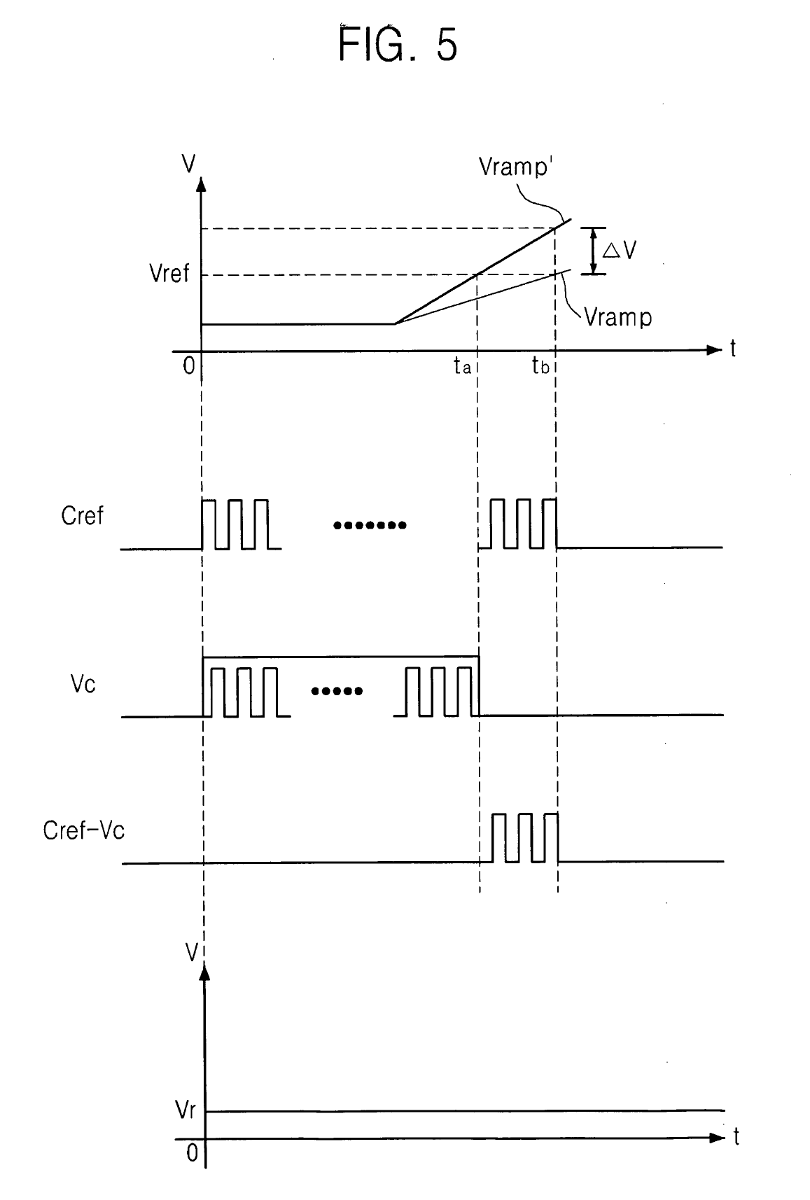

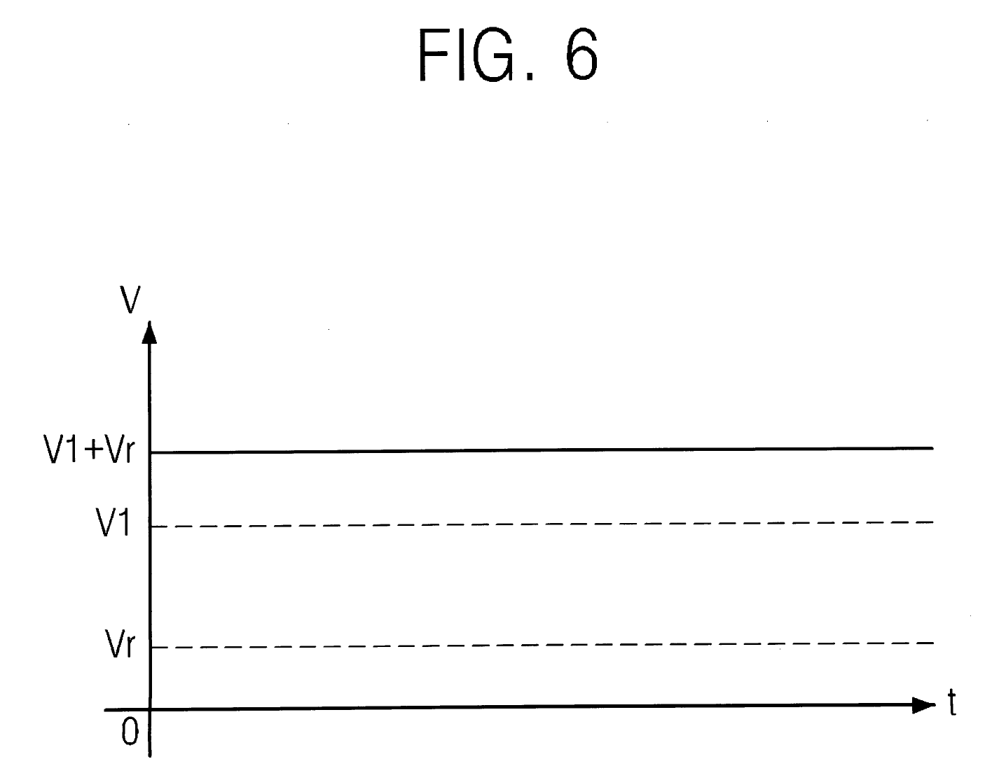

The following is a ramp signal generator according to example embodiments explained in detail referring to FIGS. 2 to 6. FIG. 2 is a schematic block diagram of a ramp signal generator of FIG. 1; FIG. 3 is an operational timing diagram of a ramp signal generation unit of FIG. 2; FIG. 4 is a circuit diagram of a comparison unit of FIG. 3; FIG. 5 is an operational timing diagram of a ramp signal correction unit of FIG. 2; FIG. 6 is a signal wave diagram in a N1 node after a correcting voltage is generated.

Referring to FIG. 2, the ramp signal generation unit 410 may be composed of an integrator including a plurality of passive elements. For example, the ramp signal generation unit 410 may include an OP-Amp OP1, a plurality of capacitors C1 and C2, and a plurality of switches S1, S2, S3, S4, and S5. In addition, the ramp signal generation unit 410 may further include a storing unit 415. The storing unit 415 may be composed of capacitors and may store a corrected voltage Vr output from the ramp signal correction unit 420. The ramp signal correction unit 420 may include a comparison unit 421, a counter 423, a digital to analog converter (hereinafter: DAC) 425, and a switch S6.

The following is the ramp signal generator 400 explained in detail referring to FIGS. 2 and 3. The ramp signal generation unit 410 may receive a plurality of bias voltages, e.g., a pair of direct current (DC) voltage V1 and V2 that each have a different amplitude, externally-supplied as a driving voltage. Additionally, the ramp signal generation unit 410 may generate a ramp signal Vramp by a turning-on or a turning-off operation with a plurality of switches S1, S2, S3, and S4. A plurality of switches S1, S2, S3, and S4 may be turned on or off by each different clock CLK1 and CLK2, respectively. In other words, the ramp signal generation unit 410 may further include a switch control unit 411, which controls turning on or off a plurality of switches S1, S2, S3, and S4, and the switch control unit 411 may control turning on or turning off of the plurality of switches S1, S2, S3, and S4 by a pair of clocks CLK1 and CLK2 which are different each other, and are externally-supplied.

When looking into the operation of the ramp signal generation unit 410, an OP-Amp OP1 may be reset by a reset switch S5. The reset switch S5 may be turned on in between time t0 to t1 on a time axis and turned off later. After the OP-Amp OP1 is reset, first switches S1 and S3 may be turned on by a first clock CLK1 in between time t1 to t2 on a time axis t. Second switches S2 and S4 may be in the OFF state.

While first switches S1 and S3 are turned on, a second voltage V2 may be input to a first input terminal, e.g., a positive (+) input terminal, of an OP-Amp OP1 and a difference value between a first voltage V1 and a second voltage V2 may be charged in a first capacitor C1. Once charging in a first capacitor C1 is completed, first switches S1 and S3 may be turned off by the second clock CLK2 at the time t2 on a time axis t while second switches S2 and S4 are turned on.

While second switches S2 and S4 are turned on, a second voltage V2 may be supplied to a first capacitor C1 and this second voltage V2 may be additionally charged to a voltage, which had been charged in advance in a first capacitor C1, e.g., a difference value between a first voltage V1 and a second voltage V2.

The OP-Amp OP1 may operate as an integrator through repetition of the processes mentioned above and output a ramp signal Vramp. An output ramp signal Vramp may be displayed in an ideal ramp wave form when a stair waveform that occurs at the time t2 on the time axis t, having a slope predetermined or given by a difference of input voltages, e.g., the difference between the first voltage V1 and a second voltage V2 and the ratio of a first capacitor C1 and a second capacitor C2, is increased as much as the number of bits corresponding to resolution of an ADC.

A ramp signal Vramp has a slope modified by a change in the characteristics of a ramp signal generation unit 410, e.g., a change in the characteristics in a plurality of capacitors C1 and C2 or a plurality of switches S1 to S5. That is, an OP-Amp1 OP1 may output an abnormal slope-changed ramp signal Vramp′ by changing an input terminal voltage of an OP-Amp1 OP1 according to the change of the characteristics by a changed process of the elements. Such an abnormal ramp signal Vramp′ may affect a following process, e.g., a process of converting an input image signal to a digital signal by using a ramp signal Vramp in an ADC 300 of FIG. 1, and also may cause an abnormal operation of an image sensor 10.

Accordingly, as illustrated in FIG. 2, a slope-changed abnormal ramp signal Vramp′ output from the ramp signal generation unit 410 may be fed back to a ramp signal correction unit 420. The ramp signal correction unit 420 may generate a correcting voltage Vc adjusting a slope of the fed-back abnormal ramp signal Vramp′ and may make a corrected ramp signal, e.g., a normal ramp signal Vramp, output from the ramp signal generation unit 410 by adjusting driving voltages V1 and V2, which are input to the ramp signal generation unit 410, by using the generated correcting voltage Vc.

The following is a detailed explanation for a ramp signal correction unit 420 referring to FIGS. 2, 4, and 5. As described above, a ramp signal correction unit 420 may include a comparison unit 421, a counter 423, a DAC 425, and a switch S6. Such a ramp signal correction unit 420 may generate a correction voltage Vc by operating at least once before an active frame operation section of an image sensor (10 of FIG. 1). That is, the ramp signal correcting unit 420 may make a normal ramp signal Vramp output at an active frame operation of an image sensor by being driven at a reserve frame operation of an image sensor and may correct an abnormal ramp signal Vramp′.

Looking into the operation of such a ramp signal correcting unit 420, a ramp signal Vramp′ may be generated by a ramp signal generating unit's operation at reserve frame section before an active frame section of an image sensor (10 of FIG. 1). A ramp signal Vramp′ output from a ramp signal generating unit 410 may be an abnormal ramp signal Vramp′ increased by a predetermined or given voltage difference ΔV compared to a normal ramp signal Vramp as illustrated in FIG. 5.

Such an abnormal ramp signal Vramp′ may be supplied by an input of a comparing unit 421. The comparing unit 421 may be composed of an OP-Amp OP2 as illustrated in FIG. 4 and outputs a comparing signal Vc by comparing a reference voltage Vref with an abnormal ramp signal Vramp′. An abnormal ramp signal Vramp′ may be input to a second input terminal, e.g., a negative input terminal, of the comparing unit 421. A reference voltage Vref may be input to a first input terminal, e.g., a positive input terminal, of the comparing unit 421.

The comparing unit 421 may generate a comparison signal Vc by comparing two input signals Vref and Vramp′. The comparison signal Vc as illustrated in FIG. 5 may have a triggering signal level at a time point when a magnitude of an abnormal ramp signal Vramp′ is substantially the same as one of a reference voltage Vref. In other words, the comparison signal Vc may be output in a first level, e.g., a higher level, in a section where an abnormal ramp signal Vramp′ is smaller than a reference voltage Vref, for example, in between time 0 to ta on a time axis t. The comparison signal Vc may be triggered (or transited) to a second level, e.g., a lower level, at the time point when the abnormal ramp signal Vramp′ becomes substantially equal to the reference voltage Vref, e.g., at a time ta on a time axis t. Accordingly, the comparison signal Vc output from the comparing unit 421 may be output as a signal having a relatively high level in between time 0 to ta on a time axis t.

An output comparison signal Vc may be supplied to a counter 423. A reference counter value Cref may be stored in a counter 423. The reference counter value Cref may be a value that counts a comparison signal output by an input of a normal ramp signal Vramp to the comparing unit 421.

The counter 423 may count a comparison signal Vc and may output a difference value Cref-Vc between a counted comparison signal and a reference count value Cref. For example, a value counted in between time 0 to tb on a time axis t may be stored as a reference count value Cref in a counter 423. Additionally, an input comparison signal Vc may be counted by a counter 423 in between time 0 to ta on a time axis t. The counter 423 may output a difference Cref-Vc between a stored reference count value Cref and a counted comparison signal Vc. The difference value Cref-Vc may be a value counted in between time ta to tb on a time axis t.

On the other hand, because a value counting a comparison signal is smaller than a stored reference count value Cref, the counter 423 may output a positive difference value Cref-Vc. Even though it is not illustrated in drawings, when a counted comparison signal value Vc is greater than a stored reference count value Cref, the counter 423 may output a negative difference value.

An output difference value Cref-Vc may be supplied to a DAC 425. The DAC 425 may convert a difference value Cref-Vc from digital to analog and may output it as a corrected voltage Vr. Because the difference value Cref-Vc supplied from a counter 423 to a DAC 425 is a positive value, a corrected voltage Vr output from the DAC 425 may also be a positive corrected voltage Vr.

The switch S6 may be turned on and a generated corrected voltage Vr may be supplied to a storage unit 415 of the ramp signal generating unit 410. The switch S6 of the ramp signal correcting unit 420 may be turned on at least once before an active frame operation section of an image sensor. That is, the switch S6 may be turned on before an active frame operation section of an image sensor and may be turned off in the active frame operation section.

Subsequently, referring to FIGS. 2 and 6, a corrected voltage stored in the storage unit 415 may be added to a first voltage V1 and may be supplied as an input voltage of an OP-Amp OP1 of the ramp signal generating unit 410. The corrected voltage Vr output from the ramp signal correction unit 420 may add or subtract either a driving voltage V1 or V2 which are input to the ramp signal generating unit 410. This may be for controlling a slope of an output ramp signal Vramp by changing a difference between driving voltages V1 and V2 which are input to an OP-Amp OP1 of a ramp signal generating unit 410.

For example, when a positive corrected voltage Vr is output from a ramp signal correction unit 420, the output positive corrected voltage Vr may correct a first driving voltage V1 by addition. In addition, as illustrated in FIG. 6, the first driving voltage V1+Vr corrected by addition may become greater than an original first driving voltage V1, and may be input to a negative input terminal of an OP-Amp OP1 of the ramp signal generating unit 410. Accordingly, a voltage of a negative input terminal of an OP-Amp OP1 may be increased, and a slope of a ramp signal Vramp to be output may be decreased.

To give an example of the opposite case which is not illustrated in drawings, when a negative corrected voltage is output from the ramp signal correction unit 420, the output negative corrected voltage may correct a first driving voltage V1 by subtraction. In addition, the first driving voltage corrected by subtraction may become smaller than an original first driving voltage V1, and may be input to a negative input terminal of an OP-Amp OP1 of a ramp signal generating unit 410. Accordingly, a voltage of a negative input terminal of an OP-Amp OP1 may be decreased and a slope of an outputted ramp signal may be increased.

That is, the ramp signal correction unit 420 may control a slope of a ramp signal Vramp by generating a corrected voltage Vr and controlling an input voltage of the ramp signal generating unit 410. The ramp signal generator according to example embodiments may supply a ramp signal whose slope is controlled at an active frame operation of an image sensor by generating a corrected voltage through feedback of a ramp signal, which is output by driving a ramp signal generator before an active frame operation of the image sensor, and controlling an input voltage of the ramp signal generator based on a corrected voltage.

Although example embodiments have been shown and described, it will be appreciated by those skilled in the art that changes may be made in these example embodiments without departing from the principles and spirit of example embodiments, the scope of which is defined in the appended claims and their equivalents.

What is claimed is:

1. A ramp signal generator comprising:
a ramp signal generation unit configured to generate a ramp signal based on an externally-supplied driving voltage; and
a ramp signal correction unit configured to feed back the ramp signal, compare the ramp signal with a reference signal, and correct the driving voltage by generating a corrected voltage from a comparison value,
wherein the ramp signal generation unit generates a slope-changed corrected ramp signal based on the corrected driving voltage.

2. The ramp signal generator of claim 1, wherein the ramp signal correction unit comprises:
a comparison unit configured to compare the ramp signal with the reference signal and output a comparison signal;
a counter configured to store a reference count value and output a difference value between the reference count value and a value which is counted until a time point when a level of the comparison signal is triggered; and
a Digital to Analog Converter (DAC) configured to convert the difference value from digital to analog and output the corrected voltage.

3. The ramp signal generator of claim 2, wherein the DAC outputs a negative corrected voltage when the difference value is negative and outputs a positive corrected voltage when the difference value is positive.

4. The ramp signal generator of claim 3, wherein the negative corrected voltage corrects the driving voltage by subtraction and the positive corrected voltage corrects the driving voltage by addition.

5. The ramp signal generator of claim 1, wherein the ramp signal correction unit operates at least once before an active frame section.

6. The ramp signal generator of claim 1, further comprising:
a switch between an input terminal of the ramp signal generation unit and an output terminal of the ramp signal correction unit,
wherein the switch is turned on at least once before an active frame section and is turned off during the active frame section.

7. The ramp signal generator of claim 1, wherein the ramp signal generating unit further comprises:
a storage unit configured to store the corrected voltage.

8. The ramp signal generator of claim 1, wherein the ramp signal generation unit is supplied with a pair of different driving voltages as an input and the corrected voltage controls a difference between the driving voltages by being added to or subtracted from one of the pair of the driving voltages.

9. The ramp signal generator of claim 1, wherein the ramp signal generation unit is an integrator including at least one OP-Amp and a capacitor.

10. An image sensor comprising:
an active pixel sensor array (APS) configured to generate an image signal by sensing light;
the ramp signal generator of claim 1; and
an analog to digital converter (ADC) configured to perform correlated double sampling and convert the image signal to a digital signal using the slope-changed corrected ramp signal.

11. The image sensor of claim 10, wherein the ramp signal correction unit comprises:
a comparison unit configured to compare the ramp signal with the reference signal and output a comparison signal;
a counter configured to store a reference count value and output a difference value between the reference count value and a value which is counted until a time point when a level of the comparison signal is triggered; and
a Digital to Analog Converter (DAC) configured to convert the difference value from digital to analog and output the corrected voltage.

12. The image sensor of claim 11, wherein the DAC outputs a negative corrected voltage when the difference value is negative and outputs a positive corrected voltage when the difference value is positive.

13. The image sensor of claim 12, wherein the negative corrected voltage corrects the driving voltage by subtraction and the positive corrected voltage corrects the driving voltage by addition.

14. The image sensor of claim 10, wherein the ramp signal correction unit operates at least once before an active frame section.

15. The image sensor of claim 10, further comprising:
a switch between an input terminal of the ramp signal generation unit and an output terminal of the ramp signal correction unit,
wherein the switch is turned on at least once before an active frame section and is turned off during the active frame section.

16. The image sensor of claim 10, wherein the ramp signal generating unit further comprises:
a storage unit configured to store the corrected voltage.

17. The image sensor of claim 10, wherein the ramp signal generation unit is supplied with a pair of different driving voltages as an input and the corrected voltage controls a difference between the driving voltages by being added to or subtracted from one of the pair of the driving voltages.

18. The image sensor of claim 10, wherein the ramp signal generation unit is an integrator including at least one OP-Amp and a capacitor.

19. The image sensor of claim 10, further comprising:
a row driver configured to drive the APS array and generate a row selection signal.

20. The image sensor of claim 19, wherein the APS array outputs a reset signal and an image signal from a row selected by the row selection signal supplied from the row driver to the ADC.
